(19) United States
(12) Patent Application Publication
(10) Pub. No.: US 2008/0142855 A1
(43) Pub. Date: Jun. 19, 2008

(54) MOS TRANSISTOR, METHOD FOR MANUFACTURING THE MOS TRANSISTOR, CMOS SEMICONDUCTOR DEVICE INCLUDING THE MOS TRANSISTOR, AND SEMICONDUCTOR DEVICE INCLUDING THE CMOS SEMICONDUCTOR DEVICE

(75) Inventors: Keiji IKEDA, Kawasaki (JP); Toshihiko MIYASHITA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/958,615

(22) Filed: Dec. 18, 2007

(30) Foreign Application Priority Data
Dec. 19, 2006 (JP) 2006-341318

(51) Int. Cl. H01L 29/94; H01L 21/8238

(52) U.S. Cl. 257/288; 438/199; 257/E21.632; 257/E29.345

(57) ABSTRACT

A MOS transistor includes a silicon substrate, a gate insulating film disposed on the silicon substrate, a gate electrode disposed on the gate insulating film, source/drain regions disposed at both sides of the gate electrode, and a stress-generating region containing a stress-generating substance. The stress-generating region is disposed within the silicon substrate away from a surface of the silicon substrate, between the source/drain regions, and under the gate electrode.

### TECHNICAL FIELD

The present invention relates to a metal-oxide semiconductor (MOS) transistor, a method for manufacturing the MOS transistor, a complementary metal-oxide semiconductor (CMOS) device including the MOS transistor, and a semiconductor device including the CMOS device. In particular, the present invention relates to a MOS transistor including a channel to be stressed, a method for manufacturing the MOS transistor, a CMOS device including the MOS transistor, and a semiconductor device including the CMOS device.

### BACKGROUND

It is known that the application of a stress on a channel in a MOS transistor improves the carrier mobility and the current driving capability of the MOS transistor. For this reason, various means of efficiently applying a stress to a channel in a MOS transistor have been proposed. Furthermore, various stressors, which generate a stress, including silicon germanium, amorphous silicon, and contact etch stop layer (CESL) films such as a SiN film have been proposed.

Among others, in P-type MOS transistors, silicon germanium (SiGe) placed in a source/drain region is being regarded as promising as means of efficiently applying a stress to a channel.

In N-type MOS transistors, means of transferring a stress caused by a CESL film formed on a gate electrode to a channel has been proposed. In another means, amorphous silicon of a gate electrode is recrystallized to apply a stress on a channel immediately below the gate electrode, while the gate electrode is capped with a SiN layer or a SiO₂ layer. This means of applying a stress to an N-type MOS transistor is known as a stress memorization technique. See U.S. Pat. Nos. 6,906,393, 7,202,120 and U.S. publication number 2007-0148835(Japanese Unexamined Patent Application Publication No. 2004-172389 and No. 2006-237263), for example.

Recent finer design of MOS transistors has lead to an increase in impurity level in a channel to counteract a short channel effect. Finer design has also resulted in the thickness of a gate insulating film being reduced. The resulting increased impurity scattering has resulted in the carrier mobility of a MOS transistor being reduced. This negates the improvement in carrier mobility resulting from a stress applied to a channel in the MOS transistor.

Hence, there is a need for another means of applying a stress to a channel to improve carrier mobility.

### SUMMARY

The present invention is directed to various embodiments of a MOS transistor having a stress-generating region buried in the silicon substrate.

### BRIEF DESCRIPTION OF THE DRAWINGS

FIG. 1AA and FIGS. 1A to 1L are schematic views illustrating a process for manufacturing an N-type MOS transistor according to Embodiment 1 of the present invention;

FIGS. 2M, 2N, 2P, 2Q, 2R, 2T, 2U, 2V, and 2X are schematic views illustrating a process for manufacturing the N-type MOS transistor according to Embodiment 1;

FIG. 3A is a table that shows the relationship between the improvement in driving current of MOS transistors and the direction of a stress, and FIG. 3B is a schematic view illustrating stresses applied to a channel in the N-type MOS transistor according to Embodiment 1;

FIG. 4AA and FIGS. 4A to 4L are schematic views illustrating a process for manufacturing an N-type MOS transistor according to Embodiment 2 of the present invention;

FIGS. 5N, 5O, 5P, 5R, 5S, 5T, 5V, 5W, and 5X are schematic views illustrating a process for manufacturing the N-type MOS transistor according to Embodiment 2;

FIGS. 6AA to 6II are schematic views illustrating a process for manufacturing the N-type MOS transistor according to Embodiment 2;

FIG. 7AA and FIGS. 7A to 7D are schematic views illustrating a process for manufacturing a CMOS device according to Embodiment 3;

FIGS. 8E to 8H are schematic views illustrating a process for manufacturing the CMOS device according to Embodiment 3; and

FIG. 9A is a schematic view of a semiconductor device that includes a logic circuit and a memory circuit, and FIGS. 9B to 9F are schematic views illustrating the layout of a CMOS device in the logic circuit.

### DETAILED DESCRIPTION OF THE EMBODIMENTS

### Embodiment 1

This embodiment describes an N-type MOS transistor that has a stress-generating region containing a stress-generating substance (stressor) disposed below a channel in the MOS transistor and a method for manufacturing the N-type MOS transistor.

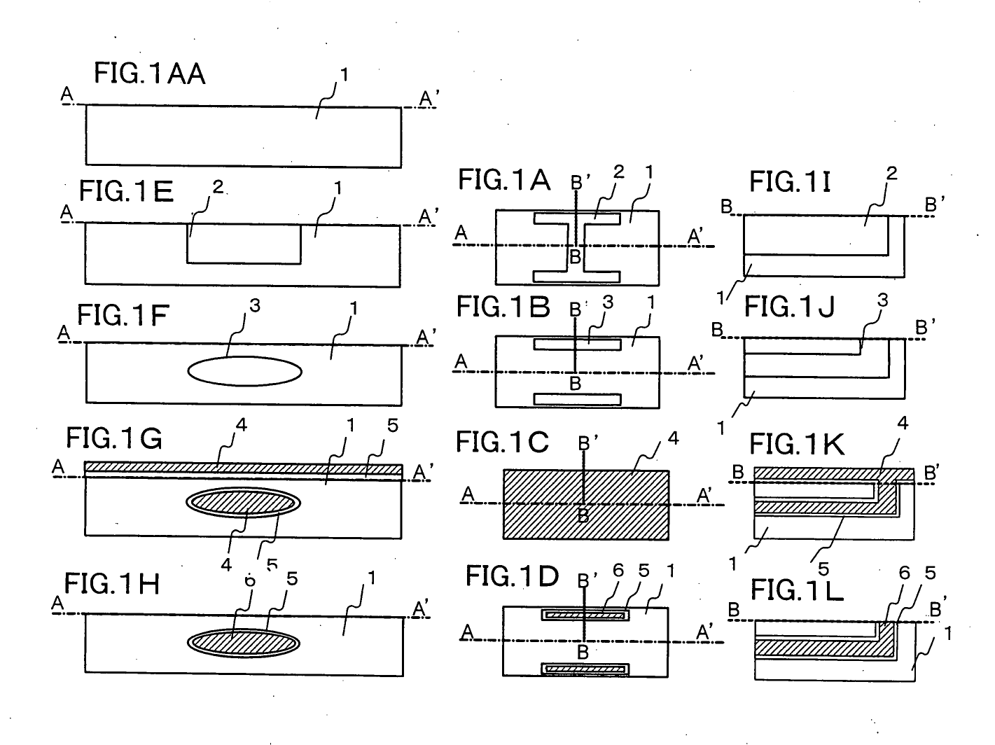

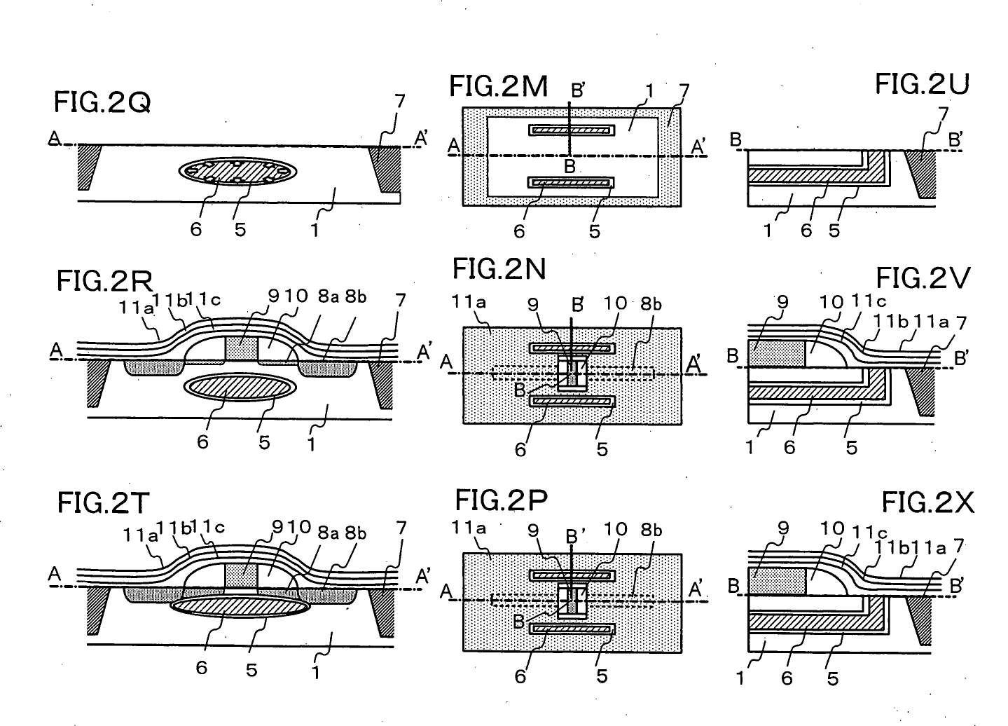

FIG. 1AA is a cross-sectional view of a substrate 1 in the N-type MOS transistor. FIGS. 1A to 1D and FIGS. 2M, 2N, and 2P are plan views of the N-type MOS transistor. FIGS. 1E to 1H and FIGS. 2Q, 2R, and 2T are cross-sectional views taken along lines A-A′ of the plan views described above. FIGS. 1I to 1L and FIGS. 2U, 2V, and 2X are cross-sectional views taken along lines B-B′ of the plan views described above.

### <Process for Manufacturing N-Type MOS Transistor According to Embodiment 1>

FIG. 1AA and FIGS. 1A to 1L are schematic views illustrating a process for manufacturing the N-type MOS transistor according to this embodiment.

FIG. 1AA illustrates a step of providing a silicon substrate 1. This step will be detailed below. First, an impurity region having a depth in the range of 0.5 μm to 5 μm in a silicon substrate 1 having P-type conductivity is doped with about 1E13/cm² of P-type impurity by ion implantation at a high acceleration energy. The silicon substrate 1 is then heat-treated to activate the impurity. Consequently, this step of providing a silicon substrate 1 can provide a silicon substrate 1 that includes a region containing a concentration of P-type impurity most suitable for the formation of an N-type MOS transistor.

FIGS. 1E, 1A, and 1I illustrate a substep of forming a groove 2 in the silicon substrate 1. The substep of forming a groove 2 in the silicon substrate 1 and a substep of closing the groove 2 constitute a step of forming a cavity 3 within the silicon substrate 1. The substep of forming a groove 2 in the silicon substrate 1 will be detailed below.

First, a silicon dioxide (SiO₂) film or a silicon nitride (SiN) film is deposited on the silicon substrate 1 as an etching mask. A photoresist is applied to the mask and is patterned to the groove 2 illustrated in FIG. 1A. A portion of the mask not covered with the photoresist is anisotropically etched to expose the silicon substrate 1, thereby transferring the pattern of the groove 2 to the mask. A portion of the silicon substrate 1 not covered with the mask is anisotropically etched to form the groove 2 in the silicon substrate 1. Finally, the photoresist and the mask are removed as illustrated in FIGS. 1A, 1E, and 1I.

As illustrated in the plan view of FIG. 1A, the groove 2 is composed of two rectangular contact portions each having a height of 0.3 μm and a width of 0.5 μm and a rectangular region connecting the two contact portions. The rectangular region is slightly larger than a channel in an N-type MOS transistor and has a width of 100 nm and the same length as the channel width. As illustrated in the cross-sectional views of FIGS. 1E and 1I, the groove 2 has a depth in the range of 60 nm to 200 nm. As described below, the rectangular region will become a cavity in which a stressor is to be placed. The contact portions will be electrically connected to the stressor in the cavity.

FIGS. 1F, 1B, and 1J illustrate a substep of closing the groove 2, which is part of the step of forming a cavity 3 within the silicon substrate 1. This substep will be detailed below. The silicon substrate 1 is annealed at 1100° C. under reduced pressure of 1 kPa in a nonoxidizing atmosphere of 100% hydrogen. The annealing closes the opening of the rectangular region to form the cavity 3, as illustrated in the cross-sectional view of FIG. 1F. As illustrated in the plan view of FIG. 1B and the cross-sectional view of FIG. 1J, the contact portions of the groove 2 are left open.

The cavity 3 has the same planar shape as the rectangular region and has a width of 100 μm and the same length as the channel width W of an N-type MOS transistor.

The cavity 3 has an elliptical cross-section. The center of the elliptical cavity 3 is located 45 nm to 150 nm away from the top surface of the silicon substrate 1. The top surface of the elliptical cavity 3 is located 30 nm to 100 nm away from the top surface of the silicon substrate 1.

As described below, the cavity 3 will become a region containing a stressor 6.

While the cavity 3 herein has an elliptical cross-section, the cavity 3 may have different cross-sections depending on the cross-section of the groove 2 or the conditions of closing the groove 2.

FIGS. 1G, 1C, and 1K illustrate a step of depositing an amorphous material 4 to place the amorphous material 4 in the cavity 3. Examples of the amorphous material 4 include amorphous silicon (Si), amorphous germanium (Ge), and amorphous silicon germanium (SiGe).

This step will be detailed below. First, the silicon substrate 1 is oxidized by heat-treatment in an oxygen atmosphere to form a silicon dioxide (SiO₂) film 5 on the inner surface of the cavity 3 and on the surface of the silicon substrate 1. The silicon dioxide (SiO₂) film 5 has a thickness in the range of 1 nm to 5 nm. The cavity 3 is then filled with the amorphous material 4 by chemical vapor deposition (CVD) at a low temperature in the range of 400° C. to 800° C. The amorphous material 4 may be amorphous silicon (Si), amorphous germanium (Ge), or amorphous silicon germanium (SiGe). Thus, the amorphous material 4 is placed in the cavity 3, as illustrated in the cross-sectional views of FIGS. 1G and 1K. As illustrated in the plan view of FIG. 1C, the top surface of the silicon substrate 1 is also covered with the amorphous material 4.

Preferably, the CVD of the amorphous material 4 is performed in the presence of an impurity to dope the amorphous material 4 with the impurity. This is because a stressor 6 produced by the conversion of the amorphous material 4 can have electrical conductivity. When the stressor 6 is used as a back-gate electrode of an N-type MOS transistor, the impurity may have N-type conductivity or P-type conductivity. It is sufficient to provide the stressor 6 with electrical conductivity. However, when the stressor 6 is used as one of double-gate electrodes of an N-type MOS transistor, the impurity preferably has N-type conductivity to make the voltage thresholds of both electrodes uniform.

FIGS. 1H, 1D, and 1L illustrate a step of converting the amorphous material 4 placed in the cavity 3 into the stressor 6, that is, a step of forming a region containing a stressor 6. This step will be detailed below. First, the amorphous material 4, such as amorphous silicon (Si), amorphous germanium (Ge), or amorphous silicon germanium (SiGe), deposited on the silicon dioxide (SiO₂) film 5 is removed by chemical mechanical polishing (CMP). The amorphous material 4 is then crystallized by heat treatment to form the stressor 6. The silicon dioxide film 5 disposed on the silicon substrate 1 is then removed.

Thus, as illustrated in the cross-sectional views of FIGS. 1H and 1L, the cavity 3 becomes the region containing a stressor 6. Furthermore, as illustrated in the plan view of FIG. 1D, the contact portions of the groove 2 appear at the surface of the silicon substrate 1.

The term “stressor” used herein means a substance that applies a stress to the silicon substrate 1. The amorphous material 4 expands during crystallization by heat treatment and thereby applies a stress to the surrounding silicon substrate 1, thus acting as the stressor 6.

FIGS. 2Q, 2M, and 2U illustrate a step of forming a device isolation region 7. This step will be detailed below. First, a silicon dioxide (SiO₂) film or a silicon nitride (SiN) film is deposited on the silicon substrate 1 as an etching mask. A photoresist is applied to the mask and is patterned to the device isolation region 7. A portion of the mask not covered with the photoresist is anisotropically etched to expose the silicon substrate 1, thereby transferring the pattern of the device isolation region 7 to the mask. A portion of the silicon substrate 1 not covered with the mask is anisotropically etched to form a groove for the device isolation region 7 in the silicon substrate 1. The mask is then removed. The groove for the device isolation region 7 is then filled with an insulator such as a silicon dioxide (SiO₂) film or a silicon nitride (SiN) film. The insulator on the silicon substrate 1 other than on the device isolation region 7 is then removed by CMP.

As illustrated in the cross-sectional views of FIGS. 2Q and 2U and the plan view of FIG. 2M, the device isolation region 7 thus formed surrounds an N-type MOS transistor region.

FIGS. 2R, 2N, and 2V illustrate a step of forming an N-type MOS transistor. The step of forming an N-type MOS transistor includes a substep of forming a gate insulating film of the N-type MOS transistor on the silicon substrate 1, a substep of forming a gate electrode 9 of the N-type MOS transistor on the gate insulating film, a substep of forming source/drain regions, which includes impurity diffusion regions 8a and 8b, of the N-type MOS transistor, and a substep of depositing CESL films 11a, 11b, and 11c on the gate electrode 9 of the N-type MOS transistor.

In the substep of forming a gate insulating film of the N-type MOS transistor on the silicon substrate 1, the silicon substrate 1 is oxidized in an oxygen atmosphere to form a silicon dioxide (SiO₂) film having a thickness of 1 nm as the gate insulating film. The gate insulating film may be a dielectric hafnium oxide film, which is generally formed by CVD.

In the substep of forming a gate electrode 9 of the N-type MOS transistor on the gate insulating film, the gate electrode 9 may be formed of polysilicon (poly-Si). In this case, a polysilicon (poly-Si) film having a thickness in the range of 20 nm to 50 nm is deposited on the gate insulating film. The polysilicon (poly-Si) film is then patterned into the gate electrode 9 by photolithography and anisotropic etching. The gate electrode 9 may be formed of silicide produced by the reaction between polysilicon (poly-Si) and a metal. In this case, after a polysilicon (poly-Si) film is patterned into the gate electrode 9, a metal layer is deposited on the gate electrode 9 and is heat-treated to produce silicide. After unreacted metal is removed, the gate electrode 9 is obtained. The gate electrode 9 may be composed only of a metal. In this case, a metal layer deposited on the silicon substrate 1 is patterned into the gate electrode 9 by photolithography and anisotropic etching.

In the substep of forming source/drain regions, which includes impurity diffusion regions 8a and 8b, of the N-type MOS transistor, the impurity diffusion regions 8a and 8b may be formed by ion implantation and heat treatment. In this case, the impurity region 8a is first doped with about 1E15/cm² of impurity at a low acceleration energy while the gate electrode 9 is used as a mask. An insulating silicon dioxide (SiO₂) film is then deposited on the silicon substrate 1 and is anisotropically etched to form insulating sidewalls 10 on both sides of the gate electrode 9. The impurity region 8b is then doped with about 1E15/cm² of impurity at a moderate acceleration energy while the gate electrode 9 and the sidewalls 10 are used as masks. After heat treatment for activating impurity, the source/drain regions including the impurity regions 8a and 8b are formed.

The junction depth of the impurity regions 8a and 8b are in the range of 5 nm to 10 nm and 30 nm to 50 nm, respectively. The region containing a stressor 6 is separated from the impurity regions 8a and 8b. In other words, the region containing a stressor 6 is located at a depth greater than the junction depths of the impurity regions 8a and 8b.

The impurity regions 8a and 8b may be doped with an impurity by solid phase diffusion, as well as ion implantation.

In the substep of depositing CESL films 11a, 11b, and 11c on the gate electrode 9 of the N-type MOS transistor, the CESL films 11a, 11b, and 11c are deposited on the gate electrode 9.

The CESL films cause a tensile stress pressing the gate electrode 9. The CESL films may be formed by the formation of a silicon nitride (SiN) film by plasma CVD using a silane (SiH₄) gas and an ammonia (NH₄) gas and subsequent dehydrogenation by ultraviolet light.

### <Structure of N-type MOS Transistor According to Embodiment 1>

As illustrated in the cross-sectional views of FIGS. 2R and 2V and the plan view of FIG. 2N, an N-type MOS transistor according to Embodiment 1 includes a silicon substrate 1, a gate insulating film disposed on the silicon substrate 1, a gate electrode 9 disposed on the gate insulating film, source/drain regions, which include impurity regions 8a and 8b, disposed at both sides of the gate electrode 9, and a stress-generating region containing a stress-generating substance (stressor 6). The stress-generating region is disposed within the silicon substrate 1 away from a surface of the silicon substrate 1, between the source/drain regions, and under the gate electrode 9.

The region containing a stressor 6 is separated from the impurity regions 8a and 8b, which constitutes the source/drain regions.

As illustrated in the plan view of FIG. 2N, the N-type MOS transistor includes regions that are electrically connected to the stress-generating substance (stressor 6) disposed on the top and the bottom of the gate electrode 9 (contact portions of the groove 2).

Furthermore, as illustrated in the cross-sectional views of FIGS. 2R and 2V, the N-type MOS transistor includes the CESL films 11a, 11b, and 11c on the gate electrode 9.

When the stressor 6 is used as a back-gate electrode of an N-type MOS transistor, the stressor 6 must be doped with an impurity to have electrical conductivity. The stressor 6 may have N-type conductivity or P-type conductivity. However, when the stressor 6 is used as one of double-gate electrodes of an N-type MOS transistor, the impurity in the stressor 6 has N-type conductivity.

In an N-type MOS transistor having such a structure, a channel in the N-type MOS transistor is subjected to a tensile stress from the stressor 6 in a source-drain direction.

Furthermore, the CESL films 11a, 11b, and 11c disposed on the gate electrode 9 presses the gate electrode 9 against the silicon substrate 1. The gate electrode 9 therefore places a tensile stress on the channel in an N-type MOS transistor in the source-drain direction. Consequently, the channel in the N-type MOS transistor is subjected to the tensile stress from the stressor 6 and the tensile stress from the gate electrode 9.

The stressor 6 electrically connected to the contact portions of the groove 2 can function as a back-gate electrode of the N-type MOS transistor. This is because the region containing the stressor 6 is separated from the source/drain regions, and therefore the surface of the region containing the stressor 6 does not function as the channel of the N-type MOS transistor.

### <N-Type MOS Transistor According to Modification of Embodiment 1>

FIGS. 2T, 2P, and 2X illustrates an N-type MOS transistor according to a modification of Embodiment 1. The positional relationship between a region containing a stressor 6 and source/drain regions is different from that of the N-type MOS transistor according to Embodiment 1. More specifically, impurity regions 8a or 8b, which constitute the source/drain regions, are in contact with the region containing a stressor 6.

Such an arrangement can be achieved by reducing the depth of a groove 2. The groove 2 is closed to form a cavity 3 at a position closer to a surface of a silicon substrate 1.

Thus, the region containing a stressor 6 becomes closer to the surface of the silicon substrate 1. More specifically, the center of the elliptical cavity 3 is located 20 nm to 40 nm away from the surface of the silicon substrate 1. The top surface of the elliptical cavity 3 is located 10 nm to 20 nm away from the surface of the silicon substrate 1.

Such a positional relationship between the region containing a stressor 6 and the impurity regions 8a and 8b may also be achieved with the region containing a stressor 6 having various shapes such as having various longitudinal or transverse dimensions.

The region containing a stressor 6 closer to the surface of the silicon substrate 1 provides a larger tensile stress for a channel in the surface of the silicon substrate 1 of the N-type MOS transistor.

The stressor 6 electrically connected to the contact portions of the groove 2 can function as one of double-gate electrodes of the N-type MOS transistor. This is because the region containing a stressor 6 is located under the other of the double-gate electrodes of the N-type MOS transistor and is in contact with the source/drain regions. The region containing a stressor 6 is in contact with the silicon substrate 1 via the silicon dioxide (SiO₂) film 5. Both sides of the region containing a stressor 6 are in contact with the source impurity region and the drain impurity region. Thus, the surface of the region containing a stressor 6 functions as a channel of the N-type MOS transistor.

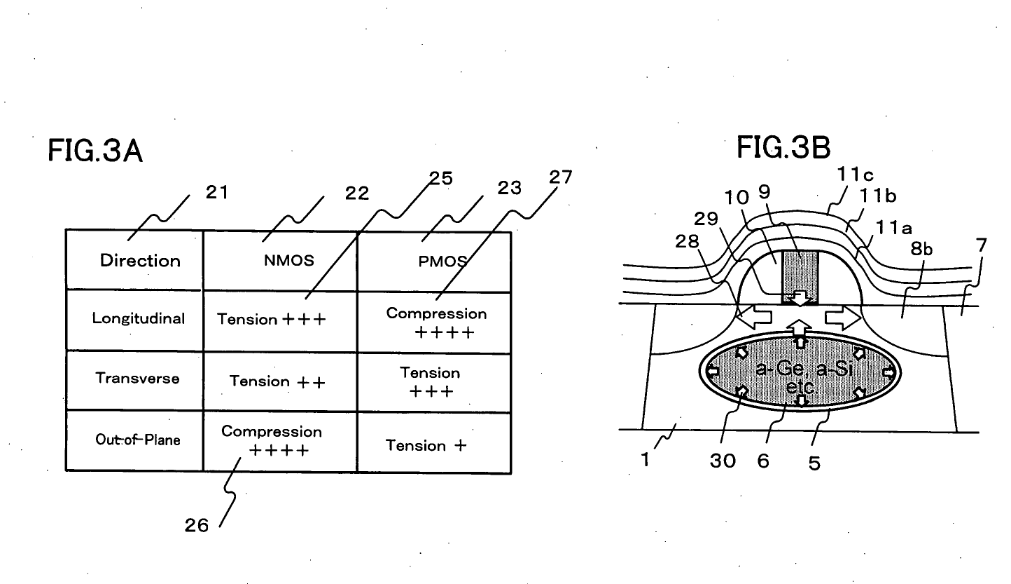

FIG. 3A is a table that shows the relationship between the improvement in driving current of MOS transistors and the direction of a stress. FIG. 3B is a schematic view illustrating stresses applied to a channel in the N-type MOS transistor according to Embodiment 1.

FIG. 3A shows the direction of a stress in a channel of an N-type MOS transistor most suitable to improve the driving current of the N-type MOS transistor and the direction of a stress in a channel of a P-type MOS transistor most suitable to improve the driving current of the P-type MOS transistor.

This table shows the conditions for improving the driving current of a metal-oxide-semiconductor field-effect transistor (MOSFET) when a longitudinal direction (X direction: source-drain direction) is a <110> direction of a semiconductor substrate 1. The table was prepared with reference to S. E. Thompson et al., IEEE Trans. Elec. Dev, pp. 1790-1797, November 2004.

The table includes Direction 21, NMOS 22, PMOS 23, Tension +++25, Compression ++++26, and Compression ++++27.

The column of Direction 21 lists the direction of a stress. The direction of a stress includes a longitudinal direction (X direction: source-drain direction), a transverse direction (Y direction: perpendicular to the source-drain direction), and an out-of-plane direction (Z direction: height direction, that is, direction perpendicular to the top surface of a semiconductor).

The column of NMOS 22 lists the direction of a stress most suitable to improve the driving current of the N-type MOS transistor.

For example, when the direction of a stress is the longitudinal direction, “Tension” (tensile stress) is most suitable to improve the driving current of the N-type MOS transistor. The symbol “+++” indicates the degree of improvement in driving current. A larger number of “+” indicates greater improvement in driving current.

Thus, “Tension +++” 25 indicates that a tensile strain in the source-drain direction improves the driving current moderately to greatly.

In the same manner, when the direction of a stress is the transverse direction, “Tension” (tensile stress) is most suitable and improves the driving current mildly to moderately (“++”). When the direction of a stress is the out-of-plane direction, “Compression” (compressive stress) is most suitable and improves the driving current greatly The column of PMOS 23 lists the direction of a stress most suitable to improve the driving current of a p-type metal-insulator-semiconductor field-effect transistor (MISFET).

The PMOS 23 is “Compression ++++” 27 for the longitudinal direction. Thus, Compression (compressive strain) is most suitable for the longitudinal direction and improves the driving current greatly.

FIG. 3B illustrates stresses applied to a channel in the N-type MOS transistor according to Embodiment 1. The N-type MOS transistor includes a silicon substrate 1, a silicon dioxide (SiO₂) film 5 disposed on a region containing a stressor 6, the stressor 6, a device isolation region 7, impurity regions 8b, which constitute source/drain regions, a gate electrode 9, sidewalls 10, and CESL films 11a, 11b, and 11c. FIG. 3B shows a stress 29 in a direction perpendicular to a top surface of the silicon substrate 1, a stress 28 parallel to the top surface of the silicon substrate 1, and a stress 30 within the region containing the stressor 6.

The stress 30 within the region containing the stressor 6 generates the stress 28 in the source/drain direction parallel to the top surface of the silicon substrate 1. FIG. 3B also shows the compressive stress 29 in the direction perpendicular to the top surface of the silicon substrate 1 from the gate electrode 9 to the region containing the stressor 6 and from the region containing the stressor 6 to the gate electrode 9.

“Tension +++” 25 and “Compression ++++” 26 shown in the table correspond to the stress 28 parallel to the top surface of the silicon substrate 1 and the stress 29 perpendicular to the top surface of the silicon substrate 1, respectively. The N-type MOS transistor according to Embodiment 1, which includes the region containing the stressor 6 disposed away from the top surface of the silicon substrate 1, between the source/drain regions, and under the gate electrode 9, therefore has an improved current driving capability.

In addition, the region containing the stressor 6 disposed closer to the channel in the N-type MOS transistor can apply a greater stress to the channel. Thus, the region containing the stressor 6 greatly improves the current driving capability of the N-type MOS transistor.

### Embodiment 2

This embodiment describes an N-type MOS transistor that has a stress-generating region containing a stress-generating substance (stressor) disposed below a channel in the MOS transistor and a method for manufacturing the N-type MOS transistor. A method for forming the stress-generating region containing a stress-generating substance (stressor) is different from that in Embodiment 1.

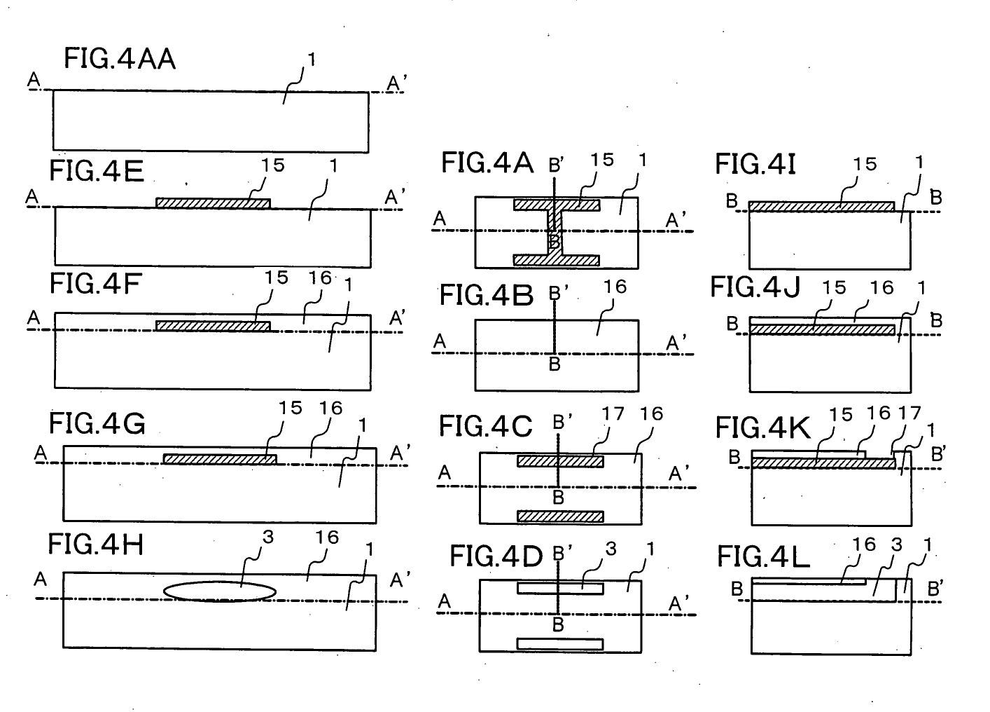

FIGS. 4A to 4D, FIGS. 5N to 5P, and FIGS. 6AA, 6BB, and 6GG are plan views. FIGS. 4E to 4H, FIGS. 5R to 5T, and FIGS. 6CC, 6DD, and 6HH are cross-sectional views taken along line A-A′ in the corresponding plan views. FIGS. 4I to 4L, FIGS. 5V to 5X, and FIGS. 6EE, 6FF, and 6II are cross-sectional views taken along line B-B′ in the corresponding plan views.

### <Process for Manufacturing N-Type MOS Transistor According to Embodiment 2>

FIG. 4AA and FIGS. 4A to 4L are schematic views illustrating a process for manufacturing an N-type MOS transistor according to Embodiment 2 of the present invention.

FIG. 4AA illustrates a step of providing a silicon substrate 1. The details of this step are the same as those of the step for providing the silicon substrate 1 illustrated in FIG. 1AA. Consequently, this step of providing a silicon substrate 1 can provide a silicon substrate 1 that includes a region containing a concentration of P-type impurity most suitable for the formation of an N-type MOS transistor.

FIGS. 4E, 4A, and 4I illustrate a substep of forming a silicon germanium (SiGe) region 15 on the silicon substrate 1. This substep is part of a step of forming a cavity 3 within the silicon substrate 1.

The step of forming a cavity 3 within the silicon substrate 1 includes the substep of forming a silicon germanium (SiGe) region 15 on the silicon substrate 1, a substep of forming an epitaxial layer 16 by the epitaxial growth of silicon (Si) on the silicon substrate 1 and on the silicon germanium (SiGe) region 15, a substep of forming contact regions 17 in the silicon germanium (SiGe) region 15, and a substep of etching silicon germanium (SiGe) to form a cavity 3.

The substep of forming a silicon germanium (SiGe) region 15 on the silicon substrate 1 will be detailed below.

First, a silicon germanium (SiGe) layer is deposited on the silicon substrate 1 by CVD at a temperature in the range of 600° C. to 800° C. A photoresist is applied to the silicon germanium (SiGe) layer and is patterned to a silicon germanium (SiGe) region 15 by photolithography. A portion of the silicon germanium (SiGe) layer not covered with the photoresist is etched to form the silicon germanium (SiGe) region 15, as illustrated in FIGS. 4A, 4E, and 4I. The remaining photoresist is removed to complete the substep.

As illustrated in the plan view of FIG. 4A, the silicon germanium (SiGe) region 15 is composed of two rectangular contact portions each having a height of 0.3 μm and a width of 0.5 μm and a rectangular region connecting the two contact portions. The rectangular region is slightly larger than a channel in an N-type MOS transistor and has a width of 100 nm and the same length as the channel width.

As illustrated in the cross-sectional views of FIGS. 4E and 4I, the silicon germanium (SiGe) region 15 has a height in the range of 30 nm to 100 nm. As described below, the rectangular region will become a cavity in which a stressor is to be placed. The contact portions will become contact regions 17 electrically connected to the stressor in the cavity.

FIGS. 4F, 4B, and 4J illustrate a substep of forming an epitaxial layer 16 by the epitaxial growth of silicon (Si) on the silicon substrate 1 and on the silicon germanium (SiGe) region 15. This substep will be detailed below. An epitaxial layer 16 having a thickness in the range of 60 nm to 200 nm is formed on the silicon substrate 1 by epitaxial growth of silicon using a silane (SiH₄) gas under reduced pressure. The epitaxial layer 16 is then polished flat by CMP.

Thus, as illustrated in the plan view of FIG. 4B, silicon is epitaxially grown over the top surface of the silicon substrate 1. As illustrated in the cross-sectional views of FIGS. 4F and 4J, the silicon germanium (SiGe) region 15 is located within the silicon substrate 1 away from a surface of the silicon substrate 1 and under a region in which a channel of the N-type MOS transistor is to be formed.

FIGS. 4G, 4C, and 4K illustrate a substep of forming contact regions 17 in the silicon germanium (SiGe) region 15, which is part of the step of forming a cavity 3 within the silicon substrate 1. This substep will be detailed below. A photoresist is applied to the top surface of the silicon substrate 1 and is patterned to the contact regions 17 in the silicon germanium (SiGe) region 15 by photolithography. Silicon on the silicon germanium (SiGe) region 15 is anisotropically etched away to shape the contact regions 17. As illustrated in the plan view of FIG. 4C, the remaining photoresist is removed to expose the contact regions 17. As illustrated in the cross-sectional views of FIGS. 4G and 4K, the contact regions 17 are formed in the epitaxial layer 16 and constitute openings of the silicon germanium (SiGe) region 15.

FIGS. 4H, 4D, and 4L illustrate a substep of etching silicon germanium (SiGe) to form a cavity 3, which is part of the step of forming a cavity 3 within the silicon substrate 1. This substep will be detailed below. As illustrated in the plan view of FIG. 4D and the cross-sectional views of FIGS. 4H and 4L, silicon germanium (SiGe) of the silicon germanium (SiGe) region 15 is isotropically etched via the contact regions 17 to form the cavity 3.

The cavity 3 has the same planar shape as the rectangular region and has a width of 100 μm and the same length as the channel width W of an N-type MOS transistor.

The cavity 3 has an elliptical cross-section. The center of the elliptical cavity 3 is located 45 nm to 150 nm away from the top surface of the silicon substrate 1. The top surface of the elliptical cavity 3 is located 30 nm to 100 nm away from the top surface of the silicon substrate 1.

As described below, the cavity 3 will become a region containing a stressor 6.

While the cavity 3 herein has an elliptical cross-section, the cavity 3 may have different cross-sections depending on the cross-section of the silicon germanium (SiGe) region 15.

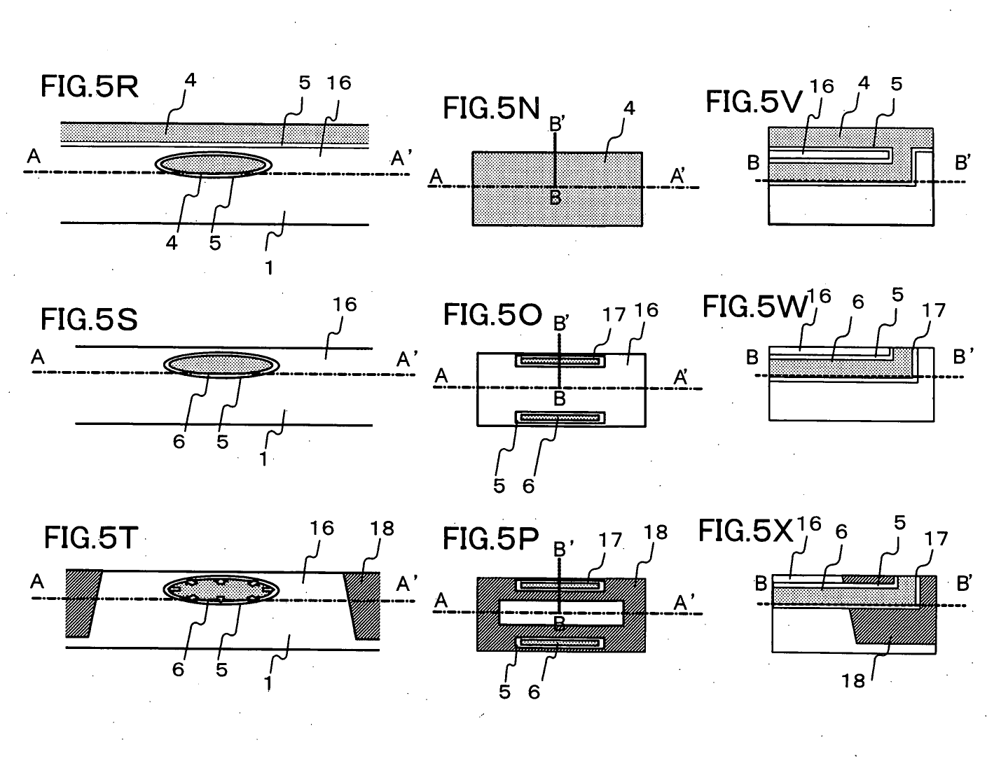

FIGS. 5N, 5R, and 5V illustrate a step of depositing an amorphous material 4 to place an amorphous material 4 in the cavity 3. The details of this step are the same as those of the step illustrated in FIGS. 1G, 1C, and 1K.

The CVD of the amorphous material 4 may be performed in the presence of an impurity to dope the amorphous material 4 with the impurity. This is because the stressor 6 produced by the conversion of the amorphous material 4 can have electrical conductivity. When the stressor 6 is used as a back-gate electrode of an N-type MOS transistor, the impurity may have N-type conductivity or P-type conductivity. It is sufficient to provide the stressor 6 with electrical conductivity. However, when the stressor 6 is used as one of double-gate electrodes of an N-type MOS transistor, the impurity may have N-type conductivity to make the voltage thresholds of both electrodes uniform.

FIGS. 5O, 5S, and 5W illustrate a step of placing the stressor 6 in the cavity 3. The details of this step are the same as those of the step illustrated in FIGS. 1H, 1D, and 1L.

Thus, as illustrated in the cross-sectional views of FIGS. 5S and 5W, the cavity 3 becomes the region containing a stressor 6. Furthermore, as illustrated in the plan view of FIG. 5O, the contact portions to the stressor 6 are produced in the contact regions 17.

The term “stressor” used herein means a substance that applies a stress to the silicon substrate 1. The amorphous material 4 expands during crystallization by heat treatment and thereby applies a stress to the surrounding silicon substrate 1, thus acting as the stressor 6.

FIGS. 5P, 5T, and 5X illustrate a step of forming a device isolation region 18. The details of this step are the same as those of the step illustrated in FIGS. 2Q, 2M, and 2U.

As illustrated in the cross-sectional views of FIGS. 5T and 5X and the plan view of FIG. 5P, the device isolation region 18 thus formed surrounds an N-type MOS transistor region. The device isolation region 18 is different from the device isolation region 7 illustrated in FIGS. 2Q, 2M, and 2U in that the inner edge of the device isolation region 18 is located between the contact portions to the stressor 6 and a gate electrode 9 in a B-B′ cross section. In the formation of the device isolation region 18, the silicon substrate 1 is anisotropically etched, whereas the region containing the stressor 6 is not etched. Silicon remaining under the region containing the stressor 6 is isotropically etched to complete the device isolation region 18.

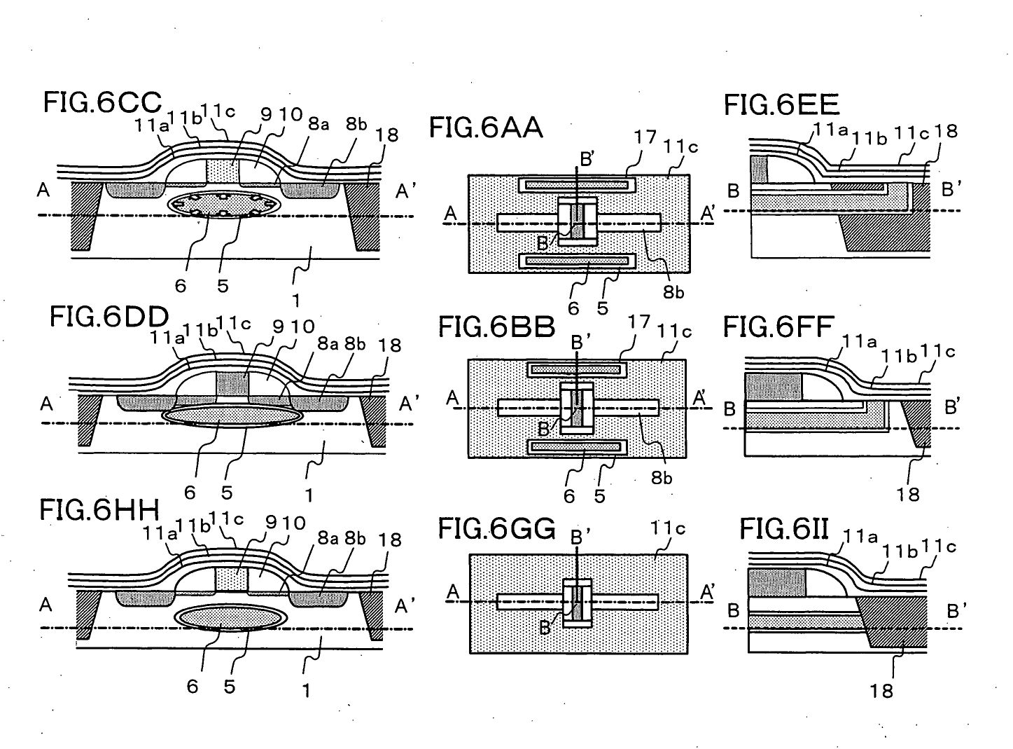

FIGS. 6AA, 6CC, and 6EE illustrate a step of forming an N-type MOS transistor. This step is similar to that illustrated in FIGS. 2R, 2N, and 2V. The step of forming an N-type MOS transistor includes a substep of forming a gate insulating film of the N-type MOS transistor, a substep of forming a gate electrode 9 of the N-type MOS transistor, a substep of forming source/drain regions, which include impurity diffusion regions 8a and 8b, of the N-type MOS transistor, and a substep of depositing CESL films 11a, 11b, and 11c on the gate electrode 9 of the N-type MOS transistor. The details of each of the substeps are the same as those of the step illustrated in FIGS. 2R, 2N, and 2V.

### <Structure of N-type MOS Transistor According to Embodiment 2>

As illustrated in the cross-sectional views of FIGS. 6CC and 6EE and the plan view of FIG. 6AA, an N-type MOS transistor according to Embodiment 2 includes a silicon substrate 1, a gate insulating film disposed on the silicon substrate 1, a gate electrode 9 disposed on the gate insulating film, source/drain regions, which include impurity regions 8a and 8b, disposed at both sides of the gate electrode 9, and a stress-generating region containing a stress-generating substance (stressor 6). The stress-generating region is disposed within the silicon substrate 1 away from a surface of the silicon substrate 1, between the source/drain regions, and under the gate electrode 9.

As illustrated in the plan view of FIG. 6AA, the N-type MOS transistor includes regions that are electrically connected to the stress-generating substance (stressor 6) disposed on the top and the bottom of the gate electrode 9 (contact regions 17).

Furthermore, as illustrated in the cross-sectional views of FIGS. 6CC and 6EE, the N-type MOS transistor includes the CESL films 11a, 11b, and 11c on the gate electrode 9.

When the stressor 6 is used as a back-gate electrode of an N-type MOS transistor, the stressor 6 must be doped with an impurity to have electrical conductivity. The stressor 6 may have N-type conductivity or P-type conductivity. However, when the stressor 6 is used as one of double-gate electrodes of an N-type MOS transistor, the impurity to be introduced into the stressor 6 preferably has N-type conductivity to make the voltage thresholds of both electrodes uniform.

In an N-type MOS transistor having such a structure, a channel in the N-type MOS transistor is subjected to a tensile stress from the stressor 6 in a source-drain direction.

Furthermore, the CESL films 11a, 11b, and 11c disposed on the gate electrode 9 presses the gate electrode 9 against the silicon substrate 1. The gate electrode 9 therefore places a tensile stress on the channel in an N-type MOS transistor in the source-drain direction. Consequently, the channel in the N-type MOS transistor is subjected to the tensile stress from the stressor 6 and the tensile stress from the gate electrode 9.

The stressor 6 electrically connected to the contact regions 17 can function as a back-gate electrode of the N-type MOS transistor. This is because the region containing the stressor 6 is separated from the source/drain regions, and therefore the surface of the region containing the stressor 6 does not function as the channel of the N-type MOS transistor.

### <N-type MOS Transistor According to First Modification of Embodiment 2>

The positional relationship between a region containing a stressor 6 and source/drain regions is different from that of the N-type MOS transistor according to Embodiment 2. More specifically, impurity regions 8a or 8b constituting the source/drain regions are in contact with the region containing a stressor 6.

Such an arrangement can be achieved by reducing the thickness of an epitaxial layer 16 formed on a silicon substrate 1 and on a silicon germanium (SiGe) region 15.

Thus, the region containing a stressor 6 becomes closer to the surface of the silicon substrate 1. More specifically, the center of an elliptical cavity 3 is located 20 nm to 40 nm away from the surface of the silicon substrate 1. The top surface of the elliptical cavity 3 is located 10 nm to 20 nm away from the surface of the silicon substrate 1.

Such a positional relationship between the region containing a stressor 6 and the impurity regions 8a and 8b may also be achieved with the region containing a stressor 6 having various shapes such as having various longitudinal or transverse dimensions.

The region containing a stressor 6 closer to the surface of the silicon substrate 1 provides a larger tensile stress for a channel in the surface of the silicon substrate 1 of the N-type MOS transistor.

The stressor 6 electrically connected to the contact regions 17 can function as one of double-gate electrodes of the N-type MOS transistor. This is because the region containing a stressor 6 is located under the other of the double-gate electrodes of the N-type MOS transistor and is in contact with the source/drain regions. The region containing a stressor 6 is in contact with the silicon substrate 1 via the silicon dioxide (SiO₂) film 5. Both sides of the region containing a stressor 6 are in contact with the source impurity region and the drain impurity region. Thus, the surface of the region containing a stressor 6 functions as a channel of the N-type MOS transistor.

### <N-type MOS Transistor According to Second Modification of Embodiment 2>

The N-type MOS transistor according to the second modification of Embodiment 2 is different from the N-type MOS transistor according to Embodiment 2 in that the N-type MOS transistor according to the second modification includes no contact region. In other words, a region containing a stressor 6 is electrically insulated within a silicon substrate 1.

Furthermore, a process of manufacturing an N-type MOS transistor according to the second modification of Embodiment 2 is different from that according to Embodiment 2 in that, in a step of forming a device isolation region 18 illustrated in FIGS. 5P, 5T, and 5X, the silicon substrate 1 is anisotropically etched, while part of the region containing a stressor 6 and contact regions 17 are etched with a different etching gas.

A stress from the isolated stressor 6 is directly applied to a channel of the N-type MOS transistor. This increases the stress in the channel of the N-type MOS transistor.

### Embodiment 3

Embodiment 3 relates to a CMOS device that includes the N-type MOS transistor according to Embodiment 1 or Embodiment 2 and a P-type MOS transistor that includes source/drain regions containing a stress-generating substance (stressor).

### <Process for Manufacturing CMOS Device According to Embodiment 3>

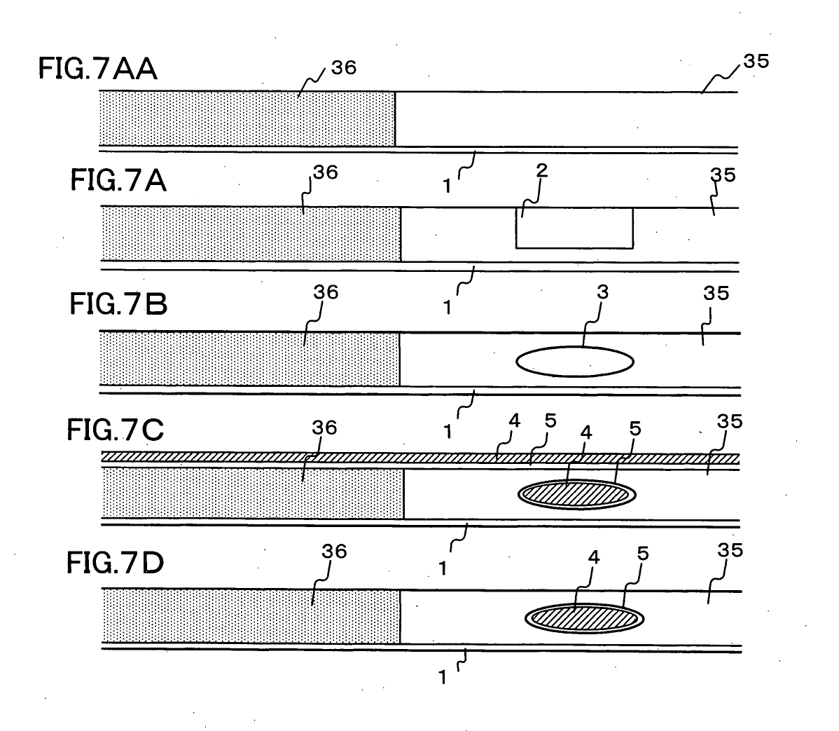

FIG. 7AA and FIGS. 7A to 7D illustrate a silicon substrate 1, a groove 2, a cavity 3, an amorphous material 4, a silicon dioxide (SiO₂) film 5, a P-type impurity region 35, and an N-type impurity region 36.

FIG. 7AA illustrates a step of providing a silicon substrate 1. First, the P-type impurity region 35 having a depth in the range of 0.5 μm to 5 μm in the silicon substrate 1 having P-type conductivity is doped with about 1E13/cm² of P-type impurity by ion implantation at a high acceleration energy. The N-type impurity region 36 having a depth in the range of 0.5 μm to 5 μm, which is different from the P-type impurity region 35, is then doped with about 5E13/cm² of N-type impurity by ion implantation at a high acceleration energy. The silicon substrate 1 is then heat-treated to activate the impurities. The silicon substrate 1 thus provided includes the P-type impurity region 35 most suitable for an N-type MOS transistor and the N-type impurity region 36 most suitable for a P-type MOS transistor.

FIG. 7A illustrates a substep of forming a groove 2 in the silicon substrate 1, which is part of a step of forming a cavity 3 in the P-type impurity region 35 in the silicon substrate 1. The substep of forming a groove 2 in the silicon substrate 1 and a substep of closing the groove 2 constitute a step of forming a cavity 3 within the silicon substrate 1.

The details of the substep of forming a groove 2 in the silicon substrate 1 are the same as those described for FIGS. 1A, 1E, and 1I.

The groove 2 is composed of two rectangular contact portions each having a height of 0.3 μm and a width of 0.5 μm and a rectangular region connecting the two contact portions. The rectangular region is slightly larger than a channel in an N-type MOS transistor and has a width of 100 nm and the same length as the channel width. As illustrated in FIG. 7A, the groove 2 has a depth in the range of 60 nm to 200 nm. As described below, the rectangular region will become a cavity 3 in which a stressor is to be placed. The contact portions will be electrically connected to the stressor in the cavity 3.

FIG. 7B illustrates a substep of closing the groove 2, which is part of a step of forming a cavity 3 in the P-type impurity region 35 in the silicon substrate 1. The details of this substep are the same as those of the substep of closing a groove 2 illustrated in FIGS. 1F, 1B, and 1J.

The cavity 3 has the same planar shape as the rectangular region and has a width of 100 μm and the same length as the channel width W of an N-type MOS transistor. The cavity 3 has an elliptical cross-section. The center of the elliptical cavity 3 is located 45 nm to 150 nm away from the top surface of the silicon substrate 1. The top surface of the elliptical cavity 3 is located 30 nm to 100 nm away from the top surface of the silicon substrate 1.

As described below, the cavity 3 will become a region containing a stressor 6.

While the cavity 3 herein has an elliptical cross-section, the cavity 3 may have different cross-sections depending on the cross-section of the groove 2 or the conditions of closing the groove 2.

FIG. 7C illustrates a step of depositing an amorphous material 4 to place the amorphous material 4 in the cavity 3. Examples of the amorphous material 4 include amorphous silicon (Si), amorphous germanium (Ge), and amorphous silicon germanium (SiGe).

The details of this step are the same as those of the step of depositing an amorphous material 4 illustrated in FIGS. 1G, 1C, and 1K.

The CVD of the amorphous material 4 may be performed in the presence of an impurity to dope the amorphous material 4 with the impurity. This is because the stressor 6 produced by the conversion of the amorphous material 4 can have electrical conductivity. When the stressor 6 is used as a back-gate electrode of an N-type MOS transistor, the impurity may have N-type conductivity or P-type conductivity. It is sufficient to provide the stressor 6 with electrical conductivity. However, when the stressor 6 is used as one of double-gate electrodes of an N-type MOS transistor, the impurity preferably has N-type conductivity to make the voltage thresholds of both electrodes uniform.

FIG. 7D illustrates a step of placing an amorphous material 4 in the cavity 3. More specifically, the amorphous material 4, such as amorphous silicon (Si), amorphous germanium (Ge), or amorphous silicon germanium (SiGe), deposited on the silicon dioxide (SiO₂) film 5 is removed by chemical mechanical polishing (CMP).

Thus, as illustrated in FIG. 7D, the cavity 3 becomes the region containing the amorphous material 4. The contact portions of the groove 2, which are to be electrically connected to the amorphous material 4, appear at the surface of the silicon substrate 1.

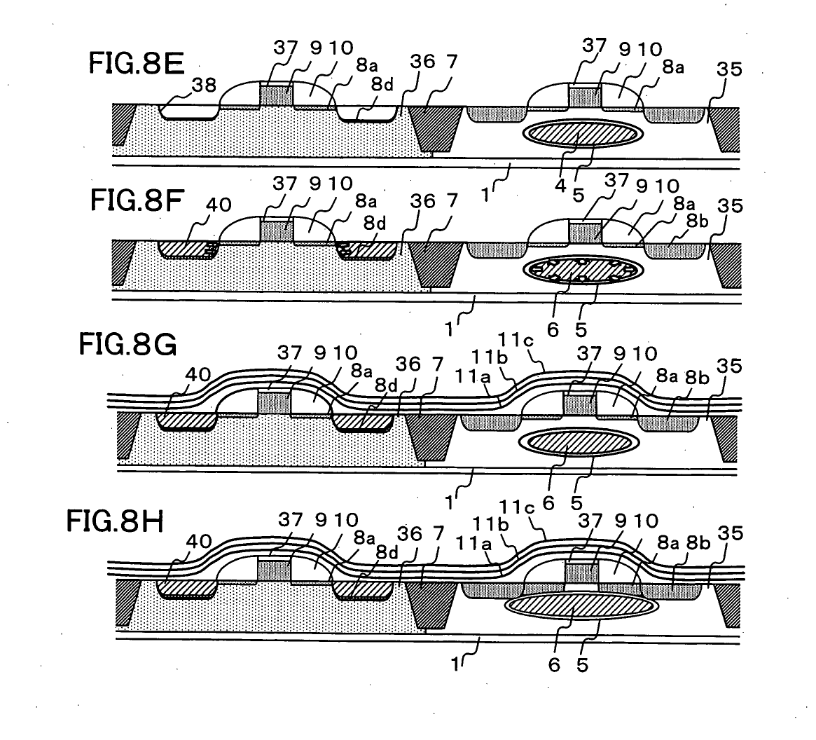

FIGS. 8E to 8H illustrate a silicon substrate 1, a groove 2, a cavity 3, an amorphous material 4, a silicon dioxide (SiO₂) film 5, a stressor 6, a device isolation region 7, an impurity diffusion region 8a, an impurity diffusion region 8b, a gate electrode 9, sidewalls 10, CESL films 11a, 11b, and 11c, a P-type impurity region 35, an N-type impurity region 36, caps 37, and grooves 38.

FIG. 8E illustrates a step of forming a device isolation region 7, a step of forming an N-type MOS transistor and a P-type MOS transistor, and a step of forming grooves 38 in source/drain regions of the P-type MOS transistor.

The details of a step of forming a device isolation region 7 are the same as those of the step of forming a device isolation region 7 illustrated in FIGS. 2Q, 2M, and 2U.

The device isolation region 7 thus formed surrounds a P-type MOS transistor region and an N-type MOS transistor region.

The step of forming an N-type MOS transistor and a P-type MOS transistor includes the substeps of forming a gate insulating film of the N-type MOS transistor and the P-type MOS transistor, forming gate electrodes 9 of the N-type MOS transistor and the P-type MOS transistor on the gate insulating film, and forming impurity diffusion regions 8a-8d of the N-type MOS transistor and the P-type MOS transistor.

In the substep of forming a gate insulating film of the N-type MOS transistor and the P-type MOS transistor, the silicon substrate 1 is oxidized in an oxygen atmosphere to form a silicon dioxide (SiO₂) film having a thickness of 1 nm as the gate insulating film. The gate insulating film may be a dielectric hafnium oxide film, which is generally formed by CVD.

In the substep of forming gate electrodes 9 of the N-type MOS transistor and the P-type MOS transistor on the gate insulating film, the gate electrodes 9 may be formed of polysilicon (poly-Si). In this case, a polysilicon (poly-Si) film and an interlayer insulating film (silicon dioxide (SiO₂) film) are deposited on the gate insulating film at a thickness in the range of 20 nm to 50 nm. The polysilicon (poly-Si) film and the interlayer insulating film are then patterned into the gate electrodes 9 and the caps 37 of the gate electrodes 9 by photolithography and anisotropic etching. The gate electrodes 9 may be formed of silicide produced by the reaction between polysilicon (poly-Si) and a metal. The gate electrodes 9 may be composed only of a metal.

In the substep of forming impurity diffusion regions 8a-8d of the N-type MOS transistor and the P-type MOS transistor, the impurity diffusion regions 8a-8d may be formed by ion implantation and heat treatment. In this case, the impurity diffusion regions 8a and 8c are doped with about 5E13/cm² of impurity at a low acceleration energy using the gate electrodes 9 and the caps 37 as the masks. The impurity is an N-type impurity for the impurity region 8a and a P-type impurity for the impurity diffusion region 8c. An insulating silicon dioxide (SiO₂) film is then deposited on the silicon substrate 1 and is anisotropically etched to form insulating sidewalls 10 on both sides of the gate electrodes 9.

The impurity diffusion regions 8b and 8d are then doped with about 1E15/cm² of impurity at a low acceleration energy. The impurity is an N-type impurity for the impurity region 8b and a P-type impurity for the impurity diffusion region 8d.

In the step of forming the grooves 38 in the source/drain regions of the P-type MOS transistor, an insulating layer (for example, silicon nitride (SiN)) is first deposited on the silicon substrate 1. A photoresist is applied to the insulating layer and is patterned to the source/drain regions disposed at both sides of the gate electrode 9 of the P-type MOS transistor by photolithography. The insulating layer is then anisotropically etched using the resist pattern as a mask. The silicon substrate 1 is then anisotropically etched to a depth in the range of 10 nm to 50 nm using the cap 37 of the gate electrode 9 of the P-type MOS transistor and the resist pattern as a mask. This forms the grooves 38 in the source/drain regions of the P-type MOS transistor, as illustrated in FIG. 8E. Finally, the resist is removed.

FIG. 8F illustrates a step of converting the amorphous material 4 disposed under the N-type MOS transistor into the stressor 6 and a step of placing silicon germanium (SiGe) in the grooves 38 in the source/drain regions of the P-type MOS transistor to form stressors 40. These steps will be detailed below. First, silicon germanium (SiGe) is epitaxially grown. Silicon germanium (SiGe) is epitaxially grown not on the insulating layer, but only in the grooves 38. Thus, silicon germanium (SiGe) deposited on the insulating layer is removed by CMP. The insulating layer is then removed to leave silicon germanium (SiGe) in the grooves 38 in the source/drain regions. The silicon germanium (SiGe) epitaxially grown in the grooves 38 is already crystallized and therefore functions as the stressors 40. The silicon substrate 1 is then heat-treated to crystallize the amorphous material 4 disposed under the N-type MOS transistor. This converts the amorphous material 4 into the stressor 6.

The stressors 40 in the source/drain regions of the P-type MOS transistor also function as source/drain electrodes. Thus, the stressors 40 must have P-type conductivity. Because source/drain electrodes other than the stressors 40 have P-type conductivity, a stressor having N-type conductivity generates a junction between the N-type stressor and the P-type source/drain electrodes and does not function as a source/drain electrode.

The CESL films deposited on the gate electrode 9 of the N-type MOS transistor cause a tensile stress. In contrast, the CESL films deposited on the gate electrode 9 of the P-type MOS transistor may cause a compressive stress. These stresses are applied to channels via the gate electrodes 9, thereby improving the carrier mobility of the N-type and P-type MOS transistors.

The CESL films that cause a tensile stress and press the gate electrode 9 of the N-type MOS transistor are formed by the formation of a silicon nitride (SiN) film by plasma CVD using a silane (SiH₄) gas and an ammonia (NH₄) gas and subsequent dehydrogenation by ultraviolet light. On the other hand, the CESL films that cause a compressive stress and pull the gate electrode 9 of the P-type MOS transistor are carbon-containing silicon nitride (SiN) films formed by plasma CVD using a silane (SiH₄) gas, an ammonia (NH₄) gas, and a carbon-containing gas.

### <Structure of CMOS Device According to Embodiment 3>

As illustrated in FIG. 8G, the CMOS device according to Embodiment 3 includes a silicon substrate 1, a P-type MOS transistor, and an N-type MOS transistor. The silicon substrate 1 includes a P-type MOS transistor region in which the P-type MOS transistor having N-type conductivity is to be formed and an N-type MOS transistor region in which the N-type MOS transistor having P-type conductivity is to be formed. The P-type MOS transistor is formed in the P-type MOS transistor region and includes source/drain regions, which include a region containing a stress-generating substance (stressor). The N-type MOS transistor is formed in the N-type MOS transistor region and includes source/drain regions and a stress-generating region containing a stress-generating substance (stressor 6). The source/drain regions are located away from a surface of the silicon substrate 1, between the source/drain regions, and under a gate electrode 9.

The N-type MOS transistor further includes regions that are electrically connected to the stress-generating substance (stressor 6) disposed on the top and the bottom of the gate electrode 9.

Furthermore, CESL films that cause a tensile stress are disposed on the gate electrode 9 of the N-type MOS transistor. On the other hand, CESL films that cause a compressive stress are disposed on the gate electrode 9 of the P-type MOS transistor.

When the stressor 6 is used as a back-gate electrode of an N-type MOS transistor, the stressor 6 may be doped with an impurity to have electrical conductivity. The stressor 6 may have N-type conductivity or P-type conductivity. However, when the stressor 6 is used as one of double-gate electrodes of an N-type MOS transistor, the impurity in the stressor 6 may have N-type conductivity to make the voltage thresholds of both electrodes uniform.

The stressors 40 in the source/drain regions of the P-type MOS transistor also function as source/drain electrodes. Thus, the stressors 40 must have P-type conductivity.

In an N-type MOS transistor having such a structure, a channel in the N-type MOS transistor is subjected to a tensile stress from the stressor 6 in a source-drain direction.

Furthermore, the CESL films 11a, 11b, and 11c disposed on the gate electrode 9 of the N-type MOS transistor presses the gate electrode 9 against the silicon substrate 1. The gate electrode 9 therefore places a tensile stress on the channel in the N-type MOS transistor in the source-drain direction. Consequently, the channel in the N-type MOS transistor is subjected to the tensile stress from the stressor 6 and the tensile stress from the gate electrode 9. On the other hand, a channel in the P-type MOS transistor is subjected to a compressive stress from the gate electrode 9. Consequently, the channel in the P-type MOS transistor is subjected to the compressive stress from the stressors 40 in the source/drain regions and the compressive stress from the gate electrode 9 of the P-type MOS transistor.

The stressor 6 electrically connected to the contact regions 17 can function as a back-gate electrode of the N-type MOS transistor. This is because the region containing the stressor 6 is separated from the source/drain regions, and therefore the surface of the region containing the stressor 6 does not function as the channel of the N-type MOS transistor.

### <CMOS Device According to Modification of Embodiment 3>

The positional relationship between a region containing a stressor 6 and source/drain regions in an N-type MOS transistor region is different from that of the CMOS device according to Embodiment 3. More specifically, impurity regions 8a or 8b, which constitute the source/drain regions, are in contact with the region containing a stressor 6.

Thus, the region containing a stressor 6 becomes closer to the surface of the silicon substrate 1. More specifically, the center of an elliptical cavity 3 is located 20 nm to 40 nm away from the surface of the silicon substrate 1. The top surface of the elliptical cavity 3 is located 10 nm to 20 nm away from the surface of the silicon substrate 1.

Such a positional relationship between the region containing a stressor 6 and the impurity regions 8a and 8b may also be achieved with the region containing a stressor 6 having various shapes such as having various longitudinal or transverse dimensions.

The region containing a stressor 6 closer to the surface of the silicon substrate 1 provides a larger tensile stress for a channel in the surface of the silicon substrate 1 of the N-type MOS transistor.

The stressor 6 electrically connected to contact regions 17 can function as one of double-gate electrodes of the N-type MOS transistor. This is because the region containing a stressor 6 is located under the other of the double-gate electrodes of the N-type MOS transistor and is in contact with the source/drain regions. The region containing a stressor 6 is in contact with the silicon substrate 1 via a silicon dioxide (SiO₂) film 5. Both sides of the region containing a stressor 6 are in contact with a source impurity region and a drain impurity region. Thus, the surface of the region containing a stressor 6 functions as a channel of the N-type MOS transistor.

### Embodiment 4

Embodiment 4 relates to a semiconductor device including the CMOS device according to Embodiment 3.

### <Structure of Semiconductor Device According to Embodiment 4>

The memory circuit is a static random memory (SRAM) 46. The memory circuit may be a dynamic random memory (DRAM). The logic circuit is an image control logic circuit 47.

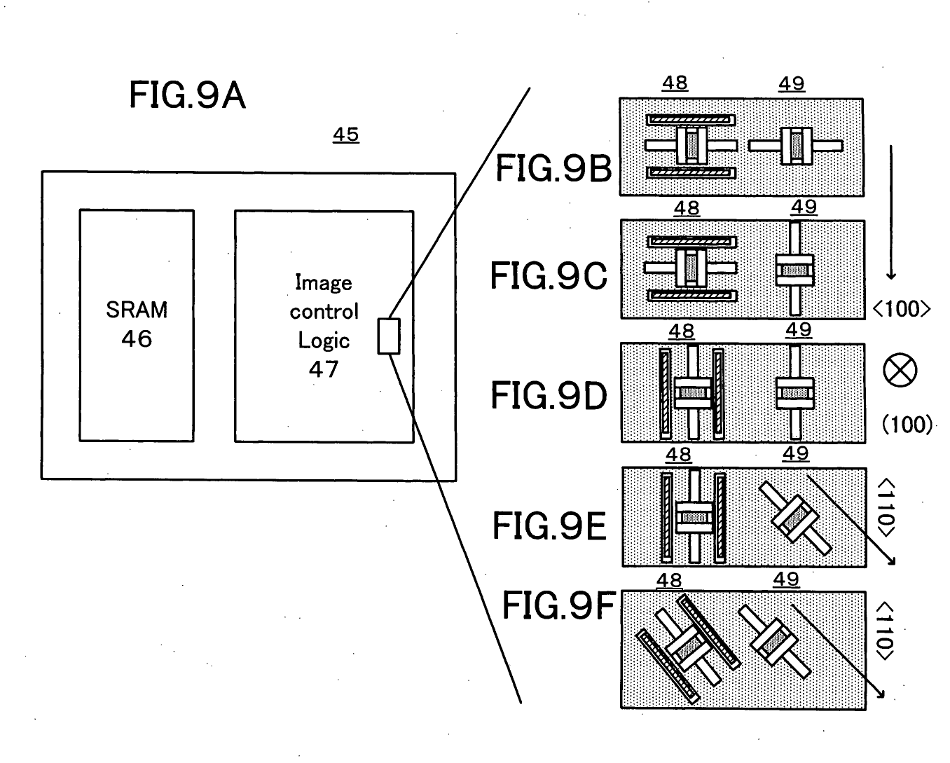

In FIG. 9B, a gate electrode of an N-type MOS transistor 48 and a gate electrode of a P-type MOS transistor 49 in the CMOS device are vertically aligned and parallel to each other. The N-type MOS transistor 48 and the P-type MOS transistor 49 are disposed on a (100) plane of a silicon substrate. Thus, stresses applied to both channels of the N-type MOS transistor 48 and the P-type MOS transistor 49 from stressors in a source-drain direction are stresses in a <100> direction. These stresses therefore increase the carrier mobility of the N-type MOS transistor 48 and the P-type MOS transistor 49. Furthermore, the source-drain direction is perpendicular to the longitudinal direction of the gate electrode.

In FIG. 9C, the gate electrode of the N-type MOS transistor 48 is placed vertically, and the gate electrode of the P-type MOS transistor 49 is placed horizontally. The N-type MOS transistor 48 and the P-type MOS transistor 49 are disposed on a (100) plane of a silicon substrate. Thus, stresses applied to both channels of the N-type MOS transistor 48 and the P-type MOS transistor 49 from stressors in a source-drain direction are stresses in a <100> direction. These stresses therefore increase the carrier mobility of the N-type MOS transistor 48 and the P-type MOS transistor 49.

In FIG. 9D, the gate electrodes of the N-type MOS transistor 48 and the P-type MOS transistor 49 are horizontally aligned. The N-type MOS transistor 48 and the P-type MOS transistor 49 are disposed on a (100) plane of a silicon substrate. Thus, stresses applied to both channels of the N-type MOS transistor 48 and the P-type MOS transistor 49 from stressors in a source-drain direction are stresses in a <100> direction. These stresses therefore increase the carrier mobility of the N-type MOS transistor 48 and the P-type MOS transistor 49.

In FIG. 9E, the gate electrode of the N-type MOS transistor 48 is placed horizontally, and the gate electrode of the P-type MOS transistor 49 is inclined at an angle of 45 degrees. The N-type MOS transistor 48 and the P-type MOS transistor 49 are disposed on a (100) plane of a silicon substrate. Thus, a stress applied to the channel of the N-type MOS transistor 48 from a stressor in a source-drain direction is a stress in a <100> direction. On the other hand, a stress applied to the channel of the P-type MOS transistor 49 from stressors in a source-drain direction is a stress in a <110> direction. These stresses therefore increase the carrier mobility of the N-type MOS transistor 48 and the P-type MOS transistor 49.

In FIG. 9F, the gate electrodes of the N-type MOS transistor 48 and the P-type MOS transistor 49 are inclined at an angle of 45 degrees and are parallel to each other. The N-type MOS transistor 48 and the P-type MOS transistor 49 are disposed on a (100) plane of a silicon substrate. Thus, stresses applied to both channels of the N-type MOS transistor 48 and the P-type MOS transistor 49 from stressors in a source-drain direction are stresses in a <110> direction. These stresses therefore increase the carrier mobility of the N-type MOS transistor 48 and the P-type MOS transistor 49.

The CMOS device has an improved current driving capability. This allows a reduction in size of the CMOS device and also of the memory circuit and the logic circuit including the CMOS device. This also reduce the size of a semiconductor device including the CMOS device according to Embodiment 3. The smaller semiconductor device exhibits a reduced load and lower power consumption.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A MOS transistor comprising:
a silicon substrate;
a gate insulating film disposed on the silicon substrate;
a gate electrode disposed on the gate insulating film;
source/drain regions disposed at both sides of the gate electrode; and
a stress-generating region containing a stress-generating substance, the stress-generating region being disposed within the silicon substrate away from a surface of the silicon substrate, between the source/drain regions, and under the gate electrode.

2. The MOS transistor according to claim 1, wherein the stress-generating region containing a stress-generating substance is disposed away from impurity regions constituting the source/drain regions.

3. The MOS transistor according to claim 1, wherein the stress-generating region containing a stress-generating substance and the source/drain regions are disposed in contact with the bottoms of the impurity regions constituting the source/drain regions.

4. The MOS transistor according to claim 1, wherein the stress-generating substance have electrical conductivity.

5. The MOS transistor according to claim 4, wherein the stress-generating substance is doped with an impurity.

6. The MOS transistor according to claim 4, further comprising a region electrically connected to the stress-generating substance within the stress-generating region.

7. The MOS transistor according to claim 1, further comprising a CESL film disposed on the gate electrode.

8. The MOS transistor according to claim 1, wherein the stress-generating substance is silicon germanium (SiGe).

9. The MOS transistor according to claim 1, wherein the stress-generating substance is in contact with the silicon substrate via an insulator.

10. A method for manufacturing a MOS transistor, comprising:
forming a cavity within a silicon substrate, the cavity being disposed away from a surface of the silicon substrate;
placing a stress-generating substance in the cavity;
forming a gate insulating film on the silicon substrate;
forming a gate electrode on the gate insulating film above the cavity; and
forming source/drain regions at both sides of the gate electrode.

11. The method for manufacturing a MOS transistor according to claim 10, wherein the step of forming a cavity within the silicon substrate comprises the substeps of forming a groove in a surface of the silicon substrate and closing the groove.

12. The method for manufacturing a MOS transistor according to claim 11, wherein part of the groove is left open in the substep of closing the groove.

13. The method for manufacturing a MOS transistor according to claim 10, wherein
the step of forming a cavity within the silicon substrate comprises the substeps of:
forming a silicon germanium (SiGe) region on the silicon substrate;
forming an epitaxial layer on the silicon substrate and on the silicon germanium (SiGe) region by the epitaxial growth of silicon (Si) to separate the silicon germanium (SiGe) region from the surface of the silicon substrate;
forming a contact region extending from the surface of the silicon substrate to the silicon germanium (SiGe) region; and
removing silicon germanium (SiGe) in the silicon germanium (SiGe) region via the contact region to form the cavity in the silicon germanium (SiGe) region.

14. The method for manufacturing a MOS transistor according to claim 10, further comprising the step of doping the stress-generating substance with an impurity.

15. The method for manufacturing a MOS transistor according to claim 10, further comprising the step of doping the stress-generating substance with an N-type impurity.

16. A semiconductor device comprising:
a silicon substrate that includes a P-type MOS transistor region in which a P-type MOS transistor having N-type conductivity is to be formed and an N-type MOS transistor region in which an N-type MOS transistor having P-type conductivity is to be formed;
an N-type MOS transistor formed in the N-type MOS transistor region, the N-type MOS transistor including a stress-generating region containing a stress-generating substance, the stress-generating region being disposed in the silicon substrate away from a surface of the silicon substrate, between the source/drain regions, and under the gate electrode; and
a P-type MOS transistor formed in the P-type MOS transistor region, the P-type MOS transistor including source/drain regions containing a stress-generating substance.

17. A method for manufacturing a CMOS device according to claim 16, comprising the steps of:
providing a silicon substrate that includes a P-type MOS transistor region in which a P-type MOS transistor is to be formed and an N-type MOS transistor region in which an N-type MOS transistor is to be formed;
forming a cavity in the N-type MOS transistor region, the cavity being away from a surface of the silicon substrate;
placing an amorphous material in the cavity in the N-type MOS transistor region;
forming a device isolation region between the P-type MOS transistor region and the N-type MOS transistor region;
forming a P-type MOS transistor in the P-type MOS transistor region;
forming an N-type MOS transistor in the N-type MOS transistor region;
epitaxially growing silicon germanium (SiGe) in source/drain regions of the P-type MOS transistor; and
converting the amorphous material into a stress-generating substance.

18. A semiconductor device according to claim 16 further comprising:
A source-drain direction of the N-type MOS transistor is a <100> or <110> direction; and
A source-drain direction of the N-type MOS transistor is a <100> or <110> direction.
